(19) United States
(12) Patent Application Publication
(10) Pub. No.: US 2026/0090274 A1
(43) Pub. Date: Mar. 26, 2026

(54) MULTIMODAL CHARGE BASED SENSING

(71) Applicant: Tacta Systems Inc., Palo Alto, CA (US)

(72) Inventors: Nahid Harjee, Sunnyvale, CA (US); Joseph C. Doll, Bend, OR (US); Harry Zhe Su, Union City, CA (US)

(21) Appl. No.: 18/894,809

(22) Filed: Sep. 24, 2024

(51) Int. Cl. H10N 30/80; G01K 7/00; G01L 1/16; H10N 30/03; H10N 30/06; H10N 30/30; H10N 39/00

(52) U.S. Cl. CPC H10N 30/802; H10N 30/03; H10N 30/06; H10N 30/302; H10N 39/00; G01K 7/00; G01L 1/16

(57) ABSTRACT

A multimodal sensor may include a first piezoelectric device, a second piezoelectric device, selection circuitry, and readout circuitry. The selection circuitry may be coupled with the first piezoelectric device and the second piezoelectric device. The selection circuitry may be controlled in a first state to connect one polarity of the devices to indicate a temperature change and may be controlled in a second state to connect an opposite polarity of the piezoelectric devices to indicate a force change. The readout circuitry may be coupled with the piezoelectric devices to generate an output indicating either the temperature change or the force change. In some implementations, the selection circuitry may be controlled in another state to disconnect the piezoelectric devices, and connect a photo sensitive element, with the readout circuitry. Other aspects are also described and claimed.

### BACKGROUND

### FIELD

This disclosure relates generally to charge based sensing and, more specifically, to multimodal charge based sensing. Other aspects are also described.

### BACKGROUND INFORMATION

A sensor array may refer to a group of sensors used for collecting information about an environment. Sensors of a sensor array may be arranged in a certain geometric configuration or pattern. Sensor arrays may enable collecting information over a greater area than a single sensor, and in two or three dimensions of the environment.

In operation, a sensor of a sensor array can generate an output signal indicating detection of a physical phenomenon. For example, a piezoelectric device can utilize the piezoelectric effect and/or the pyroelectric effect to detect changes in force, pressure, acceleration, temperature, or strain, by converting such changes to electrical charge. In another example, a capacitive sensor can utilize capacitive sensing to detect an object in proximity that may be conductive or may have a dielectric constant that is different from air.

### SUMMARY

Implementations of this disclosure include utilizing a combined, multimodal sensor having common readout circuitry to generate an output from charge generated by different sensing structures based on a type of sensing (i.e., sensing mode) that is targeted. For example, the sensing structures may include dual piezoelectric devices and/or one or more photo sensitive elements. A controller can transmit a digital input to the sensor to configure selection circuitry of the sensor to dynamically select the type of sensing to be targeted, such as temperature, force, or light. Depending on the sensing mode that is targeted, the selection circuitry, coupled with the sensing structures, can connect the sensing structures to increase charge associated with the condition to be sensed and, in some cases, cancel charge caused by an ambient condition not being sensed. The readout circuitry, in turn, can receive and amplify the charge from the sensing structures to generate an amplified output. Further, analog to digital converter (ADC) circuitry of the sensor can receive and digitize the amplified output to generate a digital output back to the controller.

In some implementations, a multimodal sensor may include a first piezoelectric device, a second piezoelectric device, selection circuitry, and readout circuitry. The selection circuitry may be coupled with the first piezoelectric device and the second piezoelectric device. The selection circuitry may be controlled in a first state to connect one polarity of the piezoelectric devices to indicate a temperature change and may be controlled in a second state to connect an opposite polarity of the piezoelectric devices to indicate a force change. The readout circuitry may be coupled with the piezoelectric devices to generate an output indicating either the temperature change or the force change.

In some implementations, a multimodal sensor may include a first piezoelectric, a second piezoelectric device, a photo sensitive element, selection circuitry, and readout circuitry. The selection circuitry may be coupled with the first piezoelectric device, the second piezoelectric device, and the photo sensitive element. The selection circuitry may be controlled in a first state to connect the piezoelectric devices, and disconnect the photo sensitive element, with the readout circuitry, and may be controlled in a second state to disconnect the piezoelectric devices, and connect the photo sensitive element, with the readout circuitry.

In some implementations, a method may include; forming a sensor die comprising selection circuitry and/or readout circuitry, wherein the sensor die includes a diaphragm formed by a deposited or bonded material layer or membrane over a cavity, such as silicon, silicon dioxide, silicon nitride; arranging a first piezoelectric device at a center of the diaphragm; and arranging a second piezoelectric device on a periphery of the diaphragm. The selection circuitry may be coupled with the first piezoelectric device and the second piezoelectric device to connect one polarity in a first state to indicate a temperature change and to connect an opposite polarity in a second state to indicate a force change. The readout circuitry may be coupled with the piezoelectric devices to generate an output indicating either the temperature change or the force change. Other aspects are also described and claimed.

The above summary does not include an exhaustive list of all aspects of the present disclosure. It is contemplated that the disclosure includes all systems and methods that can be practiced from all suitable combinations of the various aspects summarized above, as well as those disclosed in the Detailed Description below and particularly pointed out in the Claims section. Such combinations may have particular advantages not specifically recited in the above summary.

### BRIEF DESCRIPTION OF THE DRAWINGS

Several aspects of the disclosure herein are illustrated by way of example and not by way of limitation in the figures of the accompanying drawings in which like references indicate similar elements. It should be noted that references to “an” or “one” aspect in this disclosure are not necessarily to the same aspect, and they mean at least one. Also, in the interest of conciseness and reducing the total number of figures, a given figure may be used to illustrate the features of more than one aspect of the disclosure, and not all elements in the figure may be required for a given aspect.

FIG. 1 is a cross section of an example of a multimodal sensor.

FIG. 2 is a top view of an example of a multimodal sensor.

FIG. 3 is an example of circuitry of a multimodal sensor.

FIG. 4A is an example of piezoelectric devices summing their charges from a temperature change when controlled in a first state to indicate a temperature change.

FIG. 4B is an example of piezoelectric devices canceling their charges from a force change when controlled in a first state to indicate a temperature change.

FIG. 5A is an example of piezoelectric devices canceling their charges from a temperature change when controlled in a second state to indicate a force change.

FIG. 5B is an example of piezoelectric devices summing their charges from a force change when controlled in a second state to indicate a force change.

FIG. 6 is a top view of an example of matching circuitry.

FIG. 7 is a cross section of an example of matching circuitry.

FIG. 8 is a cross section of an example of a multimodal sensor with multiple dies.

FIG. 9 is an example of multimodal sensors connected in a daisy chain.

FIG. 10 is an example of multimodal sensors connected in rows and columns.

FIG. 11 is an example of a process for manufacturing a multimodal sensor with charged based sensing.

### DETAILED DESCRIPTION

In some cases it may be beneficial to utilize small sensors in a small size sensor array to sense conditions in an environment. For example, to replicate human-scale tactile sensing, it may be useful to utilize an array of force sensors, arranged in a small area, each providing sensing over a certain area. The sensors may be submillimeter in at least one in-plane dimension associated with a footprint, and/or may be arranged at a pitch of 3 millimeters or less (e.g., less than 3 millimeters (mm) between footprints).

However, reducing sensors to this size can make sensing difficult. For example, smaller sensors might not generate sufficient charge to measure a condition, such as a force or pressure being applied (i.e., insufficient signal-to-noise ratio). Sensors may also be subject to crosstalk if they respond to multiple conditions. For example, a force sensor may respond to temperature change if both change in force and temperature generate charge. Also, sensing different conditions, such as force and temperature, may involve having different sensors present in the sensor array. With a smaller size sensor array, only a limited number of sensors of each type may be present, causing the resolution of each sensing mode to be reduced.

Implementations of this disclosure address problems such as these by utilizing a combined, multimodal sensor having common readout circuitry (e.g., a charge amplifier and discrete elements) to generate an output from charges generated by different sensing structures based on a type of sensing that is targeted. For example, the sensing structures may include dual piezoelectric devices and/or one or more photo sensitive elements. A controller can transmit a digital input to the sensor to configure selection circuitry of the sensor to dynamically select the type of sensing to be targeted, such as temperature, force, or light. Depending on the sensing mode that is targeted, the selection circuitry, coupled with the sensing structures, can connect the sensing structures to increase charge associated with the condition being sensed (e.g., force) and, in some cases, cancel charge caused by an ambient condition not being sensed (e.g., temperature). The readout circuitry, in turn, can receive and amplify the charge from the sensing structures to generate an amplified output. Further, ADC circuitry of the sensor can receive and digitize the amplified output to generate a digital output back to the controller.

As a result, individual sensors in a sensor array can be dynamically configured, post-manufacture, to perform different types of sensing in the array at different times as desired. For example, one application of the array might utilize all force sensors, whereas another application might utilize an equal distribution between temperature sensors and light sensors. In either case, the same sensors may be used. Additionally, each sensor can be reduced in size, such as a microsensor, to fit in a small array while optimizing sensing for the different types of conditions.

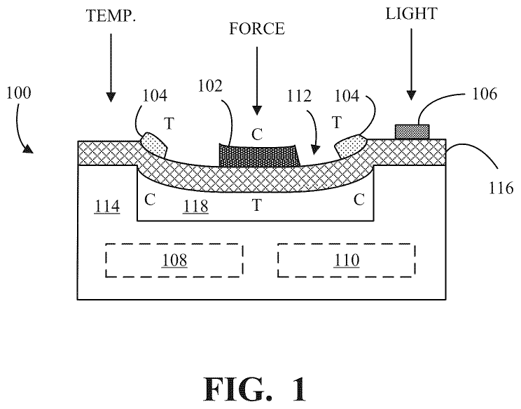

FIG. 1 is a cross section of an example of a combined, multimodal sensor 100.

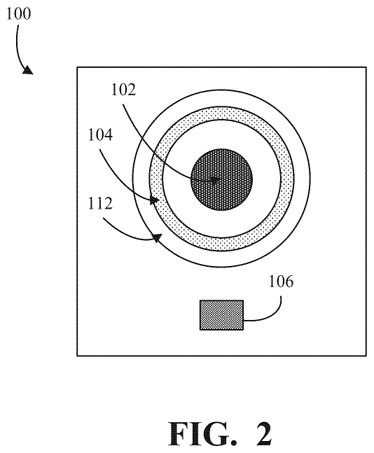

FIG. 2 is a top view of an example of the sensor 100. The sensor 100 may be a microsensor in a sensor array, e.g., to replicate human-scale tactile sensing. The sensor 100 may include dual piezoelectric devices and/or one or more photo sensitive elements (e.g., sensing structures), such as a first piezoelectric device 102, a second piezoelectric device 104, and a photo sensitive element 106 (e.g., a photodiode, photoresistor, or phototransistor). The sensor 100 may also include selection circuitry 108 and readout circuitry 110. The selection circuitry 108 and the readout circuitry 110 may each be coupled with the sensing structures, e.g., the first piezoelectric device 102, the second piezoelectric device 104, and the photo sensitive element 106. In some cases, the selection circuitry 108 and/or the readout circuitry 110 may be fabricated in a sensor die 114 as shown in FIG. 1, and in other cases, the selection circuitry 108 and/or the readout circuitry 110 may be fabricated in a converter die that may be coupled with the sensor die 114, such as the readout circuitry 110 fabricated in a converter die as shown in FIG. 8.

The first piezoelectric device 102 and the second piezoelectric device 104 (referred to collectively as the piezoelectric devices) may be fabricated on the sensor die 114. For example, piezoelectric devices may be deposited on or bonded to a layer or membrane 116 formed on the top surface of the sensor die 114. Further, the photo sensitive element 106 may be fabricated on the sensor die 114. For example, the photo sensitive element 106 may be formed in amorphous, polycrystalline, or single crystal silicon (e.g., formed as a PN junction in silicon). In some cases, the photo sensitive element 106 may be fabricated in the sensor die 114, or in the converter die, as shown in FIG. 8. The piezoelectric devices may be fabricated to have physical access to the ambient environment, and the photo sensitive element 106 may be fabricated to have optical access to the ambient environment.

The piezoelectric devices may be arranged on a diaphragm 112 formed by a deposited or bonded material layer or membrane 116, such as silicon, silicon dioxide, or silicon nitride, arranged over a cavity 118 (shown circular by way of example). In some cases, the membrane 116 may be multilayered, such as Si-SiO2. The diaphragm 112 may enable inward flexing toward the cavity 118 with an applied force. For example, the inward flexing may be caused by the sensor 100 having contact with an object or experiencing a pressurization or vibration. The first piezoelectric device 102 may be arranged at a center of the diaphragm 112 and the second piezoelectric device 104 may be arranged on a periphery of the diaphragm 112.

When a force or pressure is applied on a top surface of the diaphragm 112, the first piezoelectric device 102 may be under an amount of compression (C) (causing tension (T) on the bottom surface of the diaphragm 112 under the first piezoelectric device 102). The resulting force change may cause the first piezoelectric device 102 to generate a positive charge proportional to the compression. Also, when the force or pressure is applied, the second piezoelectric device 104 on the periphery may be under an amount of tension (T) (causing compression (C) on the bottom surface of the diaphragm 112 under the second piezoelectric device 104). The resulting force change may cause the second piezoelectric device 104 to generate a negative charge proportional to the tension. Thus, based on their arrangement, the piezoelectric devices can produce a differential response.

Further, the piezoelectric devices may be exposed to temperature changes in the environment. A positive or negative temperature change may cause the piezoelectric devices to correspondingly generate positive or negative charge. Also, the photo sensitive element 106 may be exposed to light changes in the environment. Increases or decreases in light may cause the photo sensitive element 106 to correspondingly adjust charge being generated.

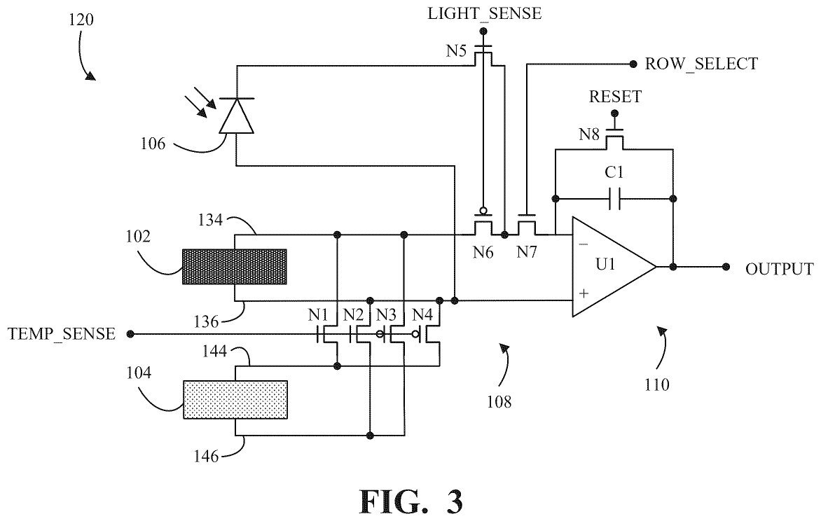

With additional reference to FIG. 3, circuitry 120 of the sensor 100 may include the selection circuitry 108 and the readout circuitry 110. The first piezoelectric device 102 may be connected between a top electrode 134 and bottom electrode 136, and the second piezoelectric device 104 may be connected between a top electrode 144 and bottom electrode 146. The selection circuitry 108 may connect to the electrodes 134, 144, 144, and 146 to selectively control their connectivity to the readout circuitry 110. For example, the selection circuitry 108 may include switches, such as transistors N1-N6 (e.g., MOSFET devices). The transistors N1-N6 may be controlled by one or more state selection signals received as a digital input from a controller, such as TEMP_SENSE and LIGHT_SENSE. For example, TEMP_SENSE may connect with gates of transistors N1-N4 where N1 and N2 are NMOS devices and N3 and N4 are PMOS devices. Also, LIGHT_SENSE may connect with gates of transistors N5-N6 where N5 is an NMOS device and N6 is a PMOS device. The selection circuitry 108 may be controlled via the state selection signals in either (1) a first state to connect one polarity of the piezoelectric devices to indicate a temperature change, (2) a second state to connect an opposite polarity of the piezoelectric devices to indicate a force or pressure change, or (3) a third state to connect the photo sensitive element 106 to indicate a light change. The controller can select one state at a time to perform the sensing of the ambient condition to be targeted. Depending on the condition, the selection circuitry 108 can connect the sensing structures to increase charge associated with the condition (e.g., force) and, in some cases, reduce the cancelation of charge caused by other conditions not being sensed (e.g., temperature).

The readout circuitry 110 selectively couples with the sensing structures (e.g., the piezoelectric devices and/or the photo sensitive element 106). The readout circuitry 110 can receive and amplify charge from the sensing structures to generate an output indicating either temperature change (first state), force change (second state), or light change (third state). For example, the readout circuitry 110 may include a charge amplifier comprising an operational amplifier U1 and a feedback capacitor C1 to amplify charge from one or more sensing structures, a row select transistor N7 to select the sensor 100 (e.g., when connected in a row/column sensor array), and a reset transistor N8 to clear the charge between readings of the sensor 100. The charge amplifier can output an analog voltage to indicate a temperature change in the first state, a force change in the second state, or a light change in the third state. Downstream ADC circuitry of the sensor 100 can receive and digitize the output from the readout circuitry 110 to generate a digital output to the controller.

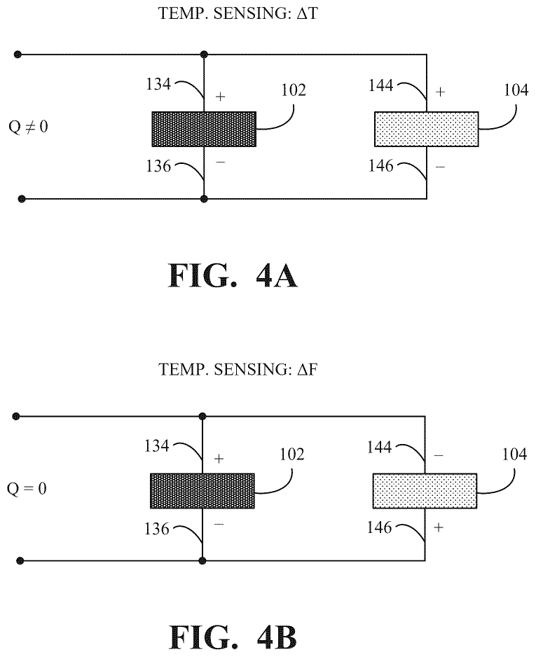

For example, for temperature sensing, TEMP_SENSE may be driven logic high by the controller and LIGHT_SENSE may be driven logic low to select the first state. This will cause N1 and N2 to turn on and N3 and N4 to turn off. This will also cause N5 to turn off and N6 to turn on. This will connect the piezoelectric devices to the readout circuitry 110 in one polarity (a parallel configuration) as shown in FIGS. 4A and 4B (e.g., top electrode 134 to top electrode 144, and bottom electrode 136 to bottom electrode 146). This will also disconnect the photo sensitive element 106 from the readout circuitry 110. As a result, the piezoelectric devices will sum their charges (Q) from temperature changes (ΔT) as shown in FIG. 4A with the same polarity attached (e.g., the charge may increase 2x). The piezoelectric devices will also cancel their charges (Q) from force or pressure changes (ΔF) as shown in FIG. 4B with an opposite polarity attached (e.g., due to their arrangement on the diaphragm 112, the charges offset one another). This will produce an optimized temperature sensor with a reduced mechanical response.

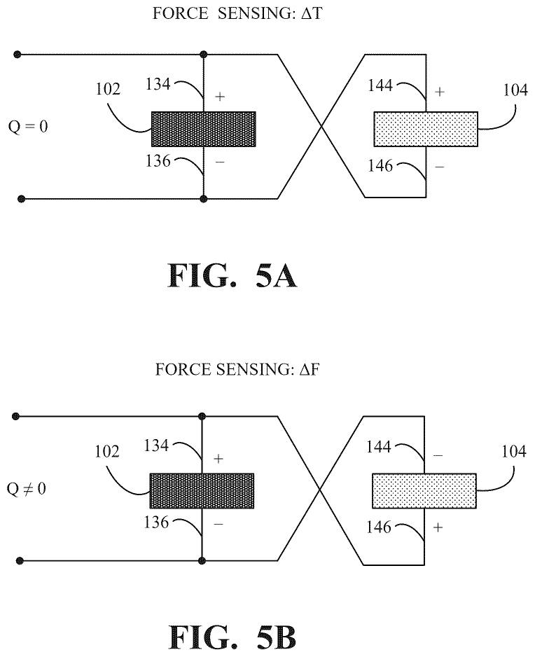

For force sensing, TEMP_SENSE may be driven logic low by the controller and LIGHT_SENSE may be driven logic low to select the second state. This will cause N1 and N2 to turn off and N3 and N4 to turn on. This will also cause N5 to turn off and N6 to turn on. This will connect the piezoelectric devices to the readout circuitry 110 in an opposite polarity (an anti-parallel configuration) as shown in FIGS. 5A and 5B (e.g., top electrode 134 to bottom electrode 146, and bottom electrode 136 to top electrode 144). This will also disconnect the photo sensitive element 106 from the readout circuitry 110. As a result, the piezoelectric devices will cancel their charges (Q) from temperature changes (ΔT) as shown in FIG. 5A with an opposite polarity attached (e.g., charges offset one another). The piezoelectric devices will also sum their charges (Q) from force or pressure changes (ΔF) as shown in FIG. 5B with the same polarity attached (e.g., due to their arrangement on the diaphragm 112, the charge may increase 2x). This will produce an optimized force sensor with a reduced temperature response, using the same readout circuitry 110.

For light sensing, LIGHT_SENSE may be driven logic high by the controller to select the third state, regardless of how TEMP_SENSE may be driven. This will cause N5 to turn on and N6 to turn off. This will connect the photo sensitive element 106 to the readout circuitry 110 and disconnect the piezoelectric devices from the readout circuitry 110. As a result, the photo sensitive element 106 will provide charge from light changes due to its optical access to the ambient environment. This will produce a light sensor without the influence of temperature or mechanical responses, using the same readout circuitry 110.

As a result, individual sensors 100 in a sensor array can be dynamically configured, post-manufacture, to perform different types of sensing in the array at different times as desired. For example, one application of the array might utilize all force sensors, whereas another application might utilize an equal distribution between temperature sensors and light sensors. In either case, the same sensors 100 may be used. Additionally, each sensor 100 can be reduced in size, such as a microsensor, to fit in a small array while optimizing sensing for the different types of conditions. This may enable a system to replicate human-scale tactile sensing, such as sensing individual points on a fingertip.

In some implementations, the sensor 100 can utilize matching circuitry to tune the piezoelectric devices with respect to one another, e.g., to match capacitances of the piezoelectric devices. For example, the matching circuitry may be utilized to match a first capacitance of the first piezoelectric device 102 with a second capacitance of the second piezoelectric device 104.

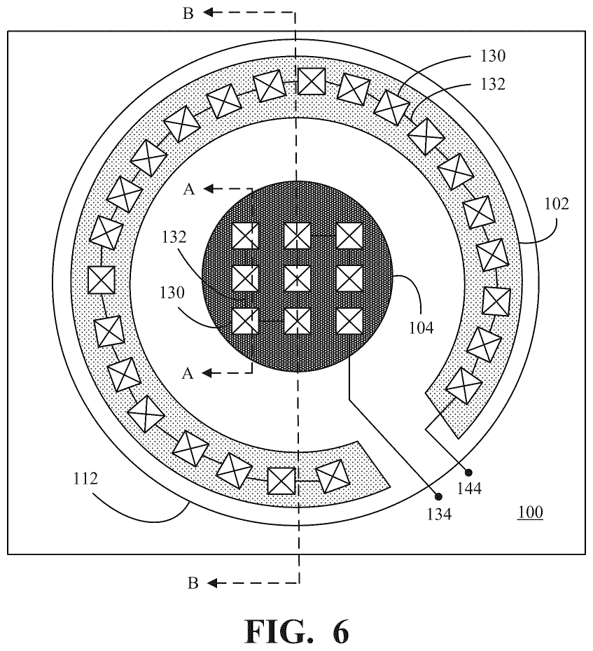

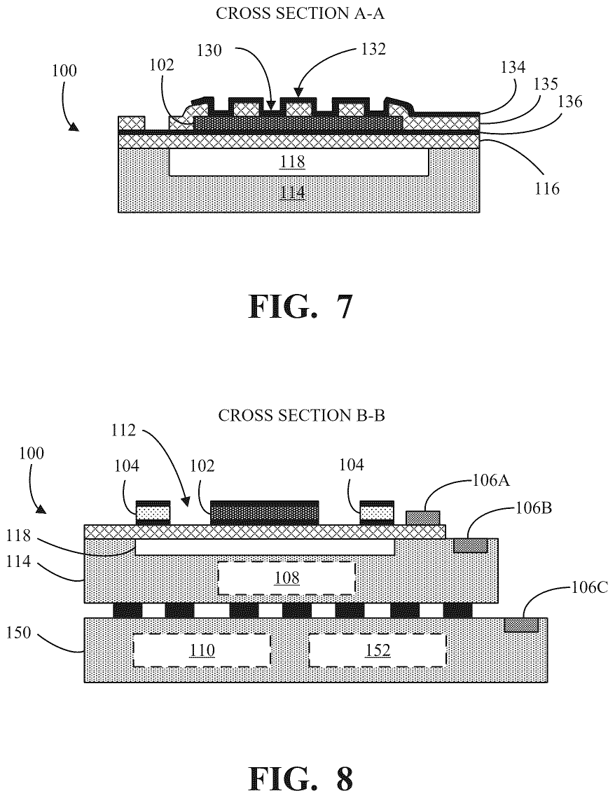

By way of example, FIG. 6 is a top view of an example of the sensor 100 utilizing matching circuitry. FIG. 7 is a cross section A-A of an example of the sensor 100 utilizing matching circuitry. The matching circuitry may include contact windows 130, in contact with a piezoelectric device, and connections 132 between the contact windows 130, connected in a daisy chain. By selectively breaking a connection 132, the number of contact windows 130 in contact with a piezoelectric device can be decreased. Conversely, by selectively making a connection 132, the number of contact windows 130 in contact with a piezoelectric device can be increased. As shown in FIG. 7, contact windows 130 provide openings through a dielectric film 135 in contact with the piezoelectric film (e.g., the first piezoelectric device 102). Thus, a contact window 130 opening increases the capacitance due to dielectric being eliminated between the electrode (e.g., the top electrode 134) and the piezoelectric film. This can enable matching one piezoelectric device (e.g., the first piezoelectric device 102) to another (e.g., the second piezoelectric device 104) to within a threshold by increasing or decreasing a capacitance of a piezoelectric device.

The matching may be performed during manufacture of the sensor 100 or in the field. In some implementations, the matching may be performed by laser trimming to tune the piezoelectric devices. For example, a connection 132 may correspond to a portion of electrode to be trimmed, leaving a cut, laser trimmed electrode (e.g., a disconnection) to decrease the number of contact windows 130 in contact with a piezoelectric device. In some implementations, the matching may be performed by programming a fuse (e.g., an electronic fuse, or e-fuse) to tune the piezoelectric devices. For example, a connection 132 may correspond to a fuse, and programming the fuse may leave a blown fuse (e.g., a disconnection) to decrease the number of contact windows 130 in contact with a piezoelectric device. In some implementations, the matching may be performed by controlling switches or transistors to tune the piezoelectric devices. For example, a connection 132 may correspond to a transistor switching to either connect an electrode to increase the number of contact windows 130 in contact with a piezoelectric device or disconnect an electrode to decrease the number of contact windows 130 in contact with the piezoelectric device. In some cases, this programming can be performed by a controller in the field.

FIG. 8 is a cross section of an example of the sensor 100 with multiple dies. In addition to the sensor die 114 (providing the diaphragm 112 via the cavity 118), the sensor 100 may have a converter die 150 coupled with the sensor die 114. The converter die 150 may include ADC circuitry 152 that can receive and digitize the output from the readout circuitry 110 to generate the digital output to the controller. The sensor die 114 could be an integrated circuit (IC) that implements circuitry coupled with the sensing structures (e.g., the piezoelectric devices and/or photo sensitive elements) on a first side and with the converter die 150 on a second side. For example, the sensor die 114 could implement circuitry to connect the piezoelectric devices and/or the photo sensitive element 106 to the converter die 150. The sensor die 114 may generate an analog output based on sensing which may be transmitted to the converter die 150. The cavity 118 may be formed in a base substrate of the sensor die 114 to enable flex of the diaphragm 112 with an application of force directed to the sensor 100.

The sensor die 114 can include a base substrate, e.g., silicon or a III-V semiconductor, for example, with circuitry and back-end-of-the-line (BEOL) routing formed using customary techniques. The BEOL routing can include landing pads, for example, for external connection, as well as routing for connection with the sensing structures and through vias. The through vias can extend through the base substrate of the sensor die 114 to provide vertical interconnection to the converter die 150. In a particular implementation, the through vias can be through silicon vias (TSVs) where the base substrate is silicon. A plurality of leads may be further connected with the sensing structures, and electrically connected with the working circuitry of the sensor die 114 and/or the through vias.

The sensing structures may provide an analog signal indicating a measurement from sensing, such as a measurement of a force, temperature, or light change. The converter die 150 may be an IC that provides power and ground to the sensor die 114 and that amplifies and converts analog signals from the sensor die 114 to digital signals at the exact location of the sensor 100 in the sensor array. Bonding between the sensor die 114 and the converter die 150 could be performed, for example, at the die level with a pick-and-place process, or at the wafer level followed by singulation. Stacking the sensor die 114 on the converter die 150 for a given sensor 100 can facilitate integration of a greater number of sensors 100 per unit area in a sensor array.

The converter die 150 may include circuitry to perform amplification and ADC of the analog output, from the sensing structures of the sensor die 114, to generate a digital representation of the analog output. For example, the converter die 150 could utilize the charge amplifier of the readout circuitry 110 to amplify charges and/or currents, from the sensor die 114, for ADC circuitry 152. The digital output could comprise 8 bits, 12 bits, or more, representing the sensed quantity. In the exemplary implementation the converter die 150 can include a base substrate that may be silicon or a III-V semiconductor, for example, with circuitry and BEOL routing formed using customary techniques. Through vias can extend through the base substrate of the converter die 150 to provide vertical interconnection to the sensor die 114. In a particular implementation, the through vias can be TSVs where the base substrate is silicon.

In some implementations, the converter die 150 may be coupled with a flexible circuit by conventional pick-and-place mounting methods (e.g., flip-chip solder bonding). The sensor die 114 and the converter die 150 may be micro-fabricated separately from the flexible circuit and subsequently assembled to the flexible circuit (which may be coupled with an article). The converter die 150 may be coupled with the electrical interconnect (e.g., copper wiring) of the sensor array that may, in turn, be coupled with other components of the system, e.g., the controller.

As discussed above with respect to FIGS. 1 and 2, one or more photo sensitive elements 106 of the sensor 100 may be formed to have optical access to the ambient environment to receive light. In a first example, a photo sensitive element 106A may be fabricated with the piezoelectric devices on the sensor die 114. For example, the photo sensitive element 106A may be formed as a PN junction in amorphous or polycrystalline silicon deposited on the sensor die 114. In a second example, a photo sensitive element 106B may be fabricated in the sensor die 114. For example, the sensor die 114 could be comprised of single-crystalline silicon that includes the selection circuitry 108, the readout circuitry 110, and/or a PN junction forming the photo sensitive element 106B. In a third example, a photo sensitive element 106C may be fabricated in the converter die 150. For example, the converter die 150 could be comprised of single-crystalline silicon that includes the ADC circuitry 152 and/or a PN junction forming the photo sensitive element 106C.

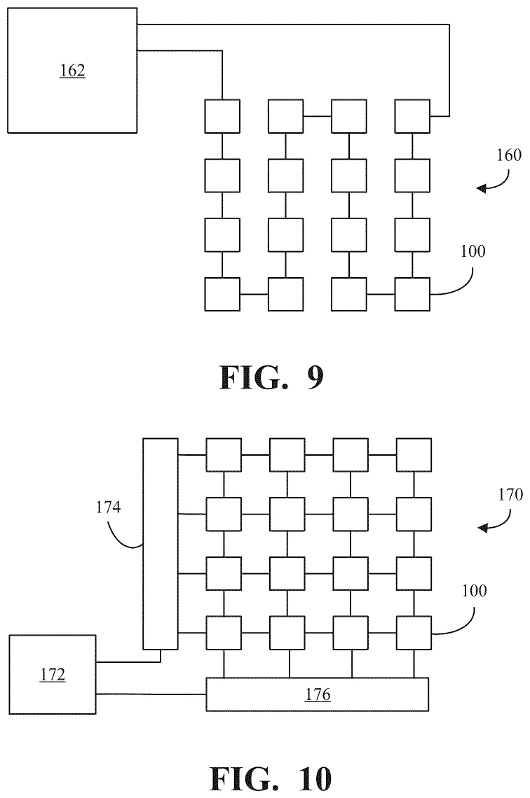

FIG. 9 is an example of a plurality of sensors 100 connected in a daisy chain to form a sensor array 160. A controller 162 can control operation of the sensor array 160. The controller 162 can transmit digital inputs to one or more sensors 100 in the sensor array 160 and receive digital outputs from one or more sensors 100 in the sensor array 160 via the daisy chain. In operation, the controller 162 can dynamically configure, post-manufacture, each sensor 100 in the sensor array 160 to perform a type of sensing. For example, at one time, the controller 162 can configure each sensor 100 in the sensor array 160 to be force sensors that sense force change, and at another time, configure half of the sensors 100 to be temperature sensors that sense temperature change and another half of the sensors 100 to be light sensors that sense temperature change. After the sensors 100 are configured, the controller 162 can trigger a first sensor 100 in the daisy chain to generate a digital output indicating sensing and, in turn, cause a trigger to a next sensor 100 in the daisy chain to generate a digital output, and so forth, to perform a read cycle of the array. The controller 162 can perform such readouts at a given frequency, such as 60 Hz. In some implementations, the controller 162 can connect with the sensors 100 via a serial bus, such as an inter-integrated circuit (I²C) bus, a serial peripheral interface (SPI) bus, or a system management (SM) bus.

FIG. 10 is an example of a plurality of sensors 100 connected in rows and columns of a sensor array 170. A controller 172 can control row drivers 174 (gate drivers) to transmit digital inputs to sensors 100 in a row and to activate a row for readout. The controller 172 can also control column readout circuitry 176 to read digital outputs of sensors 100 in an activated row. In operation, like the sensor array 160, the controller 172 can dynamically configure, post-manufacture, each sensor 100 in the sensor array 170 to perform a type of sensing. For example, at one time, the controller 172 can configure even numbered sensors 100 to be force sensors that sense force change and odd numbered sensors 100 to be temperature sensors that sense temperature change, and at another time, configure each sensor 100 in the sensor array 170 to be light sensors that sense light change, or temperature sensors that sense temperature change. After the sensors 100 are configured, the controller 172 can trigger a first row of sensors 100, via row drivers 174, to generate digital outputs for read out via column readout circuitry 176, then trigger a next row of sensors 100 to generate digital outputs for read out, and so forth, to perform a read cycle of the array. The controller 172 can perform such readouts at a given frequency, such as 60 Hz.

Reference is now made to flowcharts of examples of processes for multimodal charge based sensing and manufacturing thereof. The processes can be executed using computing devices, such as the systems, hardware, and software described with respect to FIGS. 1-10. The processes can be performed, for example, by executing a machine-readable program or other computer-executable instructions, such as routines, instructions, programs, or other code. The operations of the processes or other techniques, methods, or algorithms described in connection with the implementations disclosed herein can be implemented directly in hardware, firmware, software executed by hardware, circuitry, or a combination thereof.

For simplicity of explanation, the processes are depicted and described herein as a series of operations. However, the operations in accordance with this disclosure can occur in various orders and/or concurrently. Additionally, other operations not presented and described herein may be used. Furthermore, not all illustrated operations may be required to implement a process in accordance with the disclosed subject matter.

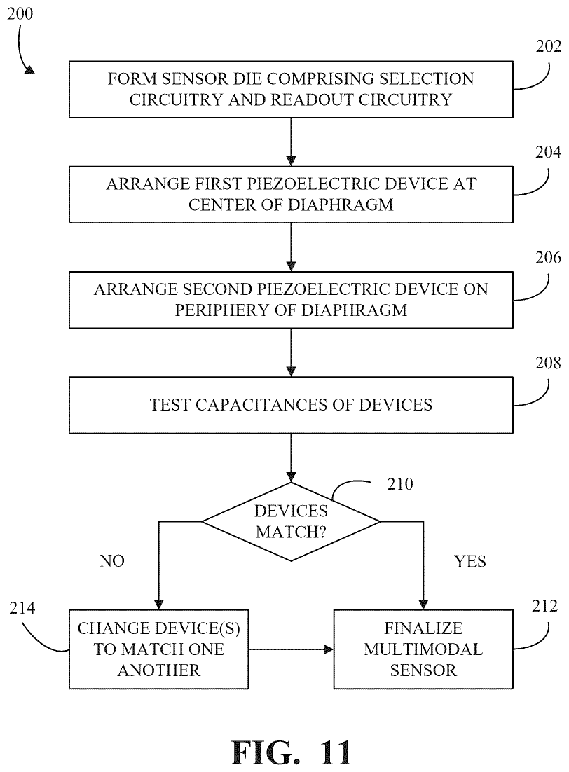

FIG. 11 is an example of a process 200 for manufacturing a multimodal sensor with charged based sensing, such as the sensor 100. At operation 202, a system can form the sensor die 114. The sensor die 114 may be formed to include selection circuitry 108, and in some cases, the readout circuitry 110. The sensor die 114 may also be formed to include the diaphragm 112. The diaphragm 112 may be formed by a membrane 116 over cavity 118.

At operation 204, the system can arrange the first piezoelectric device 102 at a center of the diaphragm 112, and at operation 206, can arrange the second piezoelectric device on a periphery of the diaphragm 112. The selection circuitry 108 may be coupled with the first piezoelectric device 102 and the second piezoelectric device 104. The selection circuitry 108 may be coupled to enable connecting one polarity in a first state to indicate a temperature change and an opposite polarity in a second state to indicate a force change. The selection circuitry 108 may also be coupled with the photo sensitive element 106 to enable indicating a light change in a third state.

In some implementations, the system can couple the converter die 150 with the sensor die 114. The system can form the converter die 150 to include the ADC circuitry 152. In some cases, the converter die 150 formed may also include the readout circuitry 110. The readout circuitry 110 may be coupled with the piezoelectric devices and/or the photo sensitive element 106 to generate an output indicating either the temperature change, the force change, or the light change.

At operation 208, the system can test the capacitances of the piezoelectric devices to determine whether they match one another to within a threshold. In some implementations, the system can induce a temperature change (e.g., heating or cooling in a chamber and/or heating with a laser to provide a temperature stimulus) and determine charge generated by the piezoelectric devices in response to the temperature change to perform the test. In some implementations, the system can induce a force change (e.g., pressurizing a chamber, vibrating, and/or mechanical stressing with an object to provide a force stimulus) and determine charge generated by the piezoelectric devices in response to the force change to perform the test.

At operation 210, if the capacitances of the piezoelectric devices match within a threshold (“Yes”), the system can finalize the sensor 100 at operation 212. This may include final testing, packaging, etc. and deployment to the field. However, if the capacitances of the piezoelectric devices do not match within a threshold (“No”), at operation 214 the system can change matching circuitry (e.g., contact windows 130 and connections 132) coupled with one or both of piezoelectric devices to match the piezoelectric devices to one another, including based on subsequent testing (e.g., operation 208). In some cases, this may include laser trimming one or more electrodes at connections 132. In some cases, this may include programming one or more fuses at connections 132. In some cases, this may include switching one or more transistors at connections 132.

For example, the sensor 100 can be configured as a force sensor, a temperature response may be measured, then contact windows 130 may be decreased by removing connections 132 until there is near zero charge from the sensor 100 due to temperature change. In another example, the sensor 100 can be configured as a temperature sensor, a force response may be measured, then contact windows 130 may be decreased by removing connections 132 until there is near zero charge from the sensor 100 due to force change. Then, at operation 212, the system can finalize the sensor 100.

As used herein, the term “circuitry” refers to an arrangement of electronic components (e.g., transistors, resistors, capacitors, and/or inductors) that is structured to implement one or more functions. For example, a circuit may include one or more transistors interconnected to form logic gates that collectively implement a logical function.

In utilizing the various aspects of the embodiments, it would become apparent to one skilled in the art that combinations or variations of the above embodiments are possible for multimodal charge based sensing. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A multimodal sensor, comprising:
a first piezoelectric device;
a second piezoelectric device;
selection circuitry coupled with the first piezoelectric device and the second piezoelectric device, wherein the selection circuitry is controlled in a first state to connect one polarity of the piezoelectric devices to indicate a temperature change, and wherein the selection circuitry is controlled in a second state to connect an opposite polarity of the piezoelectric devices to indicate a force change; and
readout circuitry, coupled with the piezoelectric devices, to generate an output indicating either the temperature change or the force change.

2. The multimodal sensor of claim 1, wherein, in the first state, the piezoelectric devices sum their charges from the temperature change and cancel their charges from force change.

3. The multimodal sensor of claim 1, wherein, in the second state, the piezoelectric devices sum their charges from force change and cancel their charges from the temperature change.

4. The multimodal sensor of claim 1, wherein the piezoelectric devices are arranged on a diaphragm that causes the first piezoelectric device to generate a positive charge based on compression and the second piezoelectric device to generate a negative charge based on tension when a force is applied on a top surface of the diaphragm.

5. The multimodal sensor of claim 1, wherein the readout circuitry comprises a charge amplifier that outputs a voltage to indicate the temperature change in the first state or the force change in the second state.

6. The multimodal sensor of claim 1, wherein the selection circuitry comprises a plurality of transistors controlled by one or more state selection signals.

7. The multimodal sensor of claim 1, further comprising:
a photo sensitive element, wherein the selection circuitry is controlled in a third state to connect the photo sensitive element to the readout circuitry.

8. The multimodal sensor of claim 1, wherein at least one of the first piezoelectric device or the second piezoelectric device is coupled with matching circuitry to match capacitances of the piezoelectric devices to one another.

9. The multimodal sensor of claim 1, wherein at least one of the first piezoelectric device or the second piezoelectric device is coupled with contact windows in a daisy chain to enable matching the first piezoelectric device with the second piezoelectric device.

10. The multimodal sensor of claim 1, further comprising:
a laser trimmed electrode causing the piezoelectric devices to match one another.

11. The multimodal sensor of claim 1, further comprising:
a programmed fuse causing the piezoelectric devices to match one another.

12. The multimodal sensor of claim 1, further comprising:
a switch to connect or disconnect an electrode to cause the piezoelectric devices to match one another.

13. A multimodal sensor, comprising:
a first piezoelectric device;
a second piezoelectric device;
a photo sensitive element; and
selection circuitry coupled with the first piezoelectric device, the second piezoelectric device, and the photo sensitive element, wherein the selection circuitry is controlled in a first state to connect the piezoelectric devices, and disconnect the photo sensitive element, with a readout circuitry, and wherein the selection circuitry is controlled in a second state to disconnect the piezoelectric devices, and connect the photo sensitive element, with the readout circuitry.

14. The multimodal sensor of claim 13, wherein the photo sensitive element is formed in silicon having optical access to an ambient environment.

15. The multimodal sensor of claim 13, wherein the piezoelectric devices and the photo sensitive element are fabricated on a sensor die, and wherein analog to digital converter (ADC) circuitry is fabricated in a converter die coupled with the sensor die.

16. The multimodal sensor of claim 13, wherein the piezoelectric devices are fabricated on a sensor die that includes the photo sensitive element, and wherein ADC circuitry is fabricated in a converter die coupled with the sensor die.

17. The multimodal sensor of claim 13, wherein the piezoelectric devices are fabricated on a sensor die, and wherein the photo sensitive element is fabricated with ADC circuitry in a converter die coupled with the sensor die.

18. The multimodal sensor of claim 13, wherein the multimodal sensor is connected in a daisy chain forming a sensor array.

19. The multimodal sensor of claim 13, wherein the multimodal sensor is connected in a row and a column of a sensor array.

20. A method, comprising:
forming a sensor die comprising selection circuitry, wherein the sensor die includes a diaphragm formed by a membrane over a cavity;
arranging a first piezoelectric device at a center of the diaphragm; and
arranging a second piezoelectric device on a periphery of the diaphragm,
wherein the selection circuitry is coupled with the first piezoelectric device and the second piezoelectric device to connect one polarity in a first state to indicate a temperature change and to connect an opposite polarity in a second state to indicate a force change, and
wherein readout circuitry is coupled with the piezoelectric devices to generate an output indicating either the temperature change or the force change.

21. The method of claim 20, further comprising:
matching a first capacitance of the first piezoelectric device with a second capacitance of the second piezoelectric device.

22. The method of claim 20, further comprising:
changing circuitry coupled with at least one of the first piezoelectric device or the second piezoelectric device to match the piezoelectric devices to one another based on a charge generated in response to the temperature change.

23. The method of claim 20, further comprising:
changing circuitry coupled with at least one of the first piezoelectric device or the second piezoelectric device to match the piezoelectric devices to one another based on a charge generated in response to the force change.

24. The method of claim 20, further comprising:
laser trimming an electrode in contact with the first piezoelectric device or the second piezoelectric device to match the piezoelectric devices to one another.

25. The method of claim 20, further comprising:
programming a fuse in contact with the first piezoelectric device or the second piezoelectric device to match the piezoelectric devices to one another.
